(19) United States
(12) Patent Application Publication
(10) Pub. No.: US 2026/0165074 A1
(43) Pub. Date: Jun. 11, 2026

(54) PACKAGING EQUIPMENT AND PACKAGING METHOD

(71) Applicant: SILICONWARE PRECISION INDUSTRIES CO., LTD., Taichung City (TW)

(72) Inventor: Chun-Sheng YEH, Taichung City (TW)

(21) Appl. No.: 19/188,760

(22) Filed: Apr. 24, 2025

(30) Foreign Application Priority Data
Dec. 6, 2024 (TW) 113147524

(51) Int. Cl. H01L 21/67; H01L 21/56

(52) U.S. Cl. CPC H10P 72/0441; H10P 72/0431; H10W 74/016

(57) ABSTRACT

A packaging equipment and a packaging method are provided. An electronic module is placed in a molding device, and the molding device is used to perform a molding operation to form an encapsulation layer on the electronic module. Then, a humidifying device is used to humidify the encapsulation layer. Later, a drying device is used to perform a drying operation to remove moisture from the encapsulation layer, and at the same time, the electronic module can be shaped.

### CROSS-REFERENCE TO RELATED APPLICATIONS

The present application is based upon and claims the right of priority to TW Patent Application No. 113147524, filed on Dec. 6, 2024, the disclosure of which is hereby incorporated by reference herein in its entirety for all purposes.

### BACKGROUND

### 1. Technical Field

The present disclosure relates to a semiconductor equipment, and more particularly, to a packaging equipment and a packaging method for a semiconductor device.

### 2. Description of Related Art

In response to the increasingly important and widespread application of high performance computing (HPC) technology in the real world nowadays, such as the development of medical technology, such as the development of cancer drugs, or the automatic sensing detection computing of self-driving cars, etc., the semiconductor packages used in the equipment applied in these fields are mostly fan-out package (FOPKG) structures. For example, structures such as fan-out multi-chip module (FOMCM) and fan-out embedded bridge (FOEB) die have multi-chip/high number of circuit layers/large fan-out size/high heat dissipation design requirements.

FIG. 1A to FIG. 1C are schematic cross-sectional views illustrating a manufacturing method of a conventional semiconductor package 1.

As shown in FIG. 1A, a circuit structure 10 is disposed on a carrier 9, and an inactive surface 11b of at least one semiconductor chip 11 is disposed on the circuit structure 10 via a chip-placing adhesive layer 18, wherein the semiconductor chip 11 has a plurality of conductive bumps 12 on an active surface 11a.

As shown in FIG. 1B, a molding process is performed to form an encapsulating colloid 15 on the circuit structure 10, and the encapsulating colloid 15 covers the semiconductor chip 11.

As shown in FIG. 1C, a wiring structure 16 is formed on the encapsulating colloid 15, so that the wiring structure 16 is electrically connected to the plurality of conductive bumps 12, and a plurality of conductive elements 17 such as of controlled-collapse chip connection (C4) bump specification are formed on the wiring structure 16 for subsequent processes.

However, in the manufacturing method of the conventional semiconductor package 1, after the molding process, the overall structure may warp significantly (such as resembling a smiling face or a crying face), which may cause difficulties or inability to operate when subsequent stations put the overall structure into machines. It is more likely that the semiconductor package 1 (especially the semiconductor chip 11) will be cracked.

Therefore, how to overcome the above-mentioned drawbacks of the prior art has become an urgent issue to be solved.

### SUMMARY

In view of the various deficiencies of the prior art, the present disclosure provides a packaging equipment, which comprises: a molding device configured to form an encapsulation layer on an electronic module; and a humidifying device configured to be connected to the molding device to humidify the encapsulation layer.

The present disclosure also provides a packaging method, which comprises: placing an electronic module in a molding device to form an encapsulation layer on the electronic module; and placing the electronic module formed with the encapsulation layer in a humidifying device to humidify the encapsulation layer.

In the aforementioned packaging equipment and packaging method, after the encapsulation layer absorbs moisture, placing the electronic module formed with the encapsulation layer in a drying device to remove moisture from the encapsulation layer while shaping the electronic module formed with the encapsulation layer.

In the aforementioned packaging equipment and packaging method, the electronic module includes a carrier structure and electronic elements disposed on the carrier structure.

In the aforementioned packaging equipment and packaging method, the electronic module is in a circular or rectangular form.

In the aforementioned packaging equipment and packaging method, the humidifying device is used to place the electronic module formed with the encapsulation layer in a high-humidity environment to allow the encapsulation layer to absorb moisture.

In the aforementioned packaging equipment and packaging method, the drying device uses a pressure oven or is fixed with a clamp to perform pressure baking to remove moisture from the encapsulation layer.

In the aforementioned packaging equipment and packaging method, the molding device is a molding mold including an upper mold and a lower mold.

In the aforementioned packaging equipment and packaging method, the humidifying device is a humidifying chamber.

In the aforementioned packaging equipment and packaging method, the drying device is an oven.

As can be seen from the above, in the packaging equipment and packaging method of the present disclosure, an electronic module is placed in a molding device for a molding operation. After an encapsulation layer is formed, the electronic module is moved to a humidifying device, and the humidifying device is used to perform a humidifying operation to the encapsulation layer. Then, the electronic module is moved to a drying device, and the drying device is used to perform a drying operation to remove moisture from the encapsulation layer and fully solidify the encapsulation layer. At the same time, the electronic module's warpage caused by the deformation of the encapsulation layer can be shaped within a certain extent to prevent the problem of cracking from occurring to the electronic package.

### BRIEF DESCRIPTION OF THE DRAWINGS

FIG. 1A to FIG. 1C are schematic cross-sectional views illustrating a manufacturing method of a conventional semiconductor package.

FIG. 2 is a flowchart illustrating a packaging method according to the present disclosure.

FIG. 3A to FIG. 3C are schematic views of a packaging equipment according to the present disclosure.

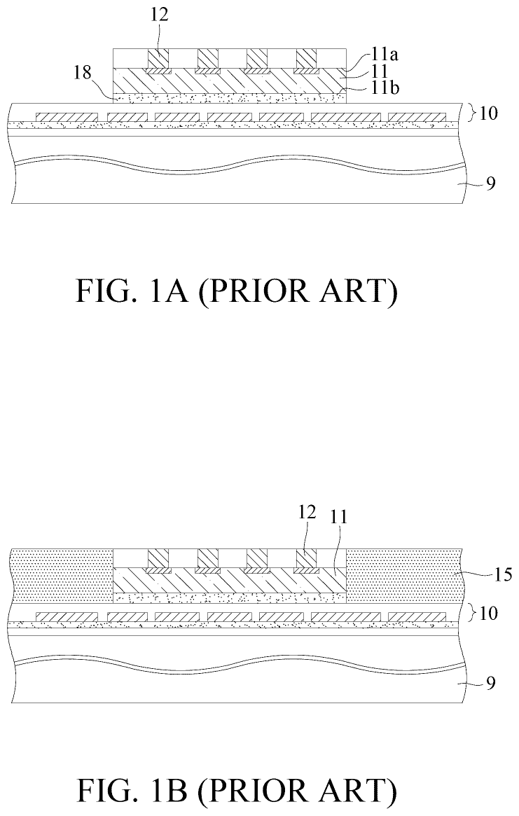

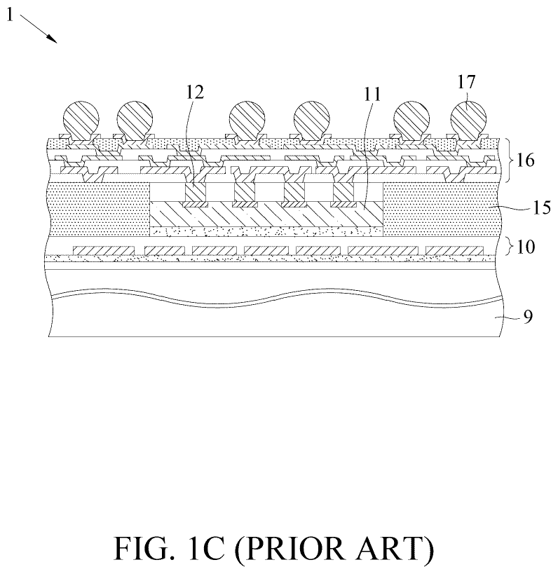

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

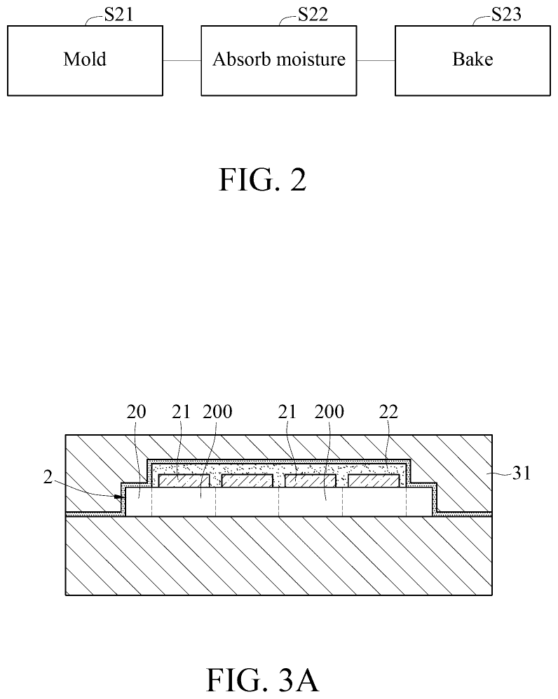

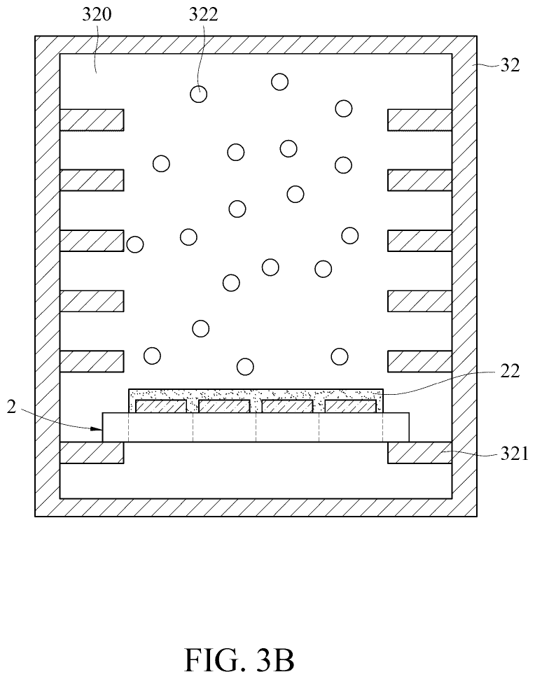

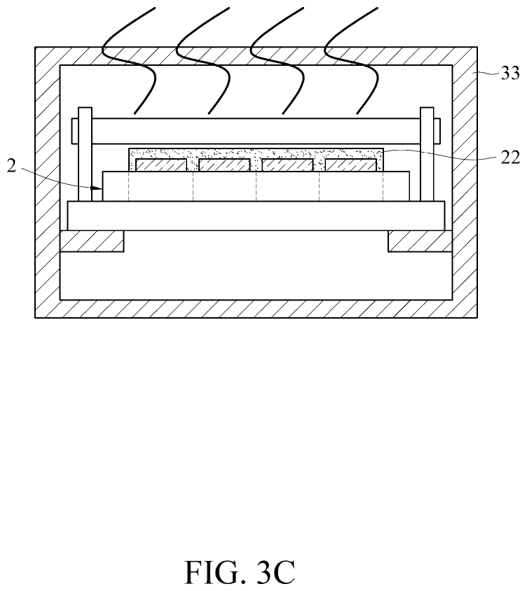

FIG. 2 is a flowchart illustrating a packaging method according to the present disclosure, and FIG. 3A to FIG. 3C are schematic views of a packaging equipment according to the present disclosure.

Please refer to FIG. 2 and FIG. 3A at the same time. First, the packaging method includes step S21: performing a molding operation. An electronic module 2 is placed in a molding device 31, and the molding device 31 is used to perform the molding operation.

In one embodiment, the molding device 31 is, for example, a molding mold including an upper mold and a lower mold (but is not limited to as such). The electronic module 2 can be in a circular wafer form with a diameter of 8 inches to 18 inches or a panel form with a rectangular side length of 300 mm to 700 mm. The electronic module 2 includes a carrier structure 20 (having a plurality of carrier units 200) and a plurality of electronic elements 21 disposed on the carrier structure 20 (each of the carrier units 200 is provided with at least one electronic element 21). The electronic module 2 is placed in the molding device 31, and the molding device 31 is used to perform a molding operation to form an encapsulation layer 22 on the electronic module 2, wherein the electronic module 2 may be warped after the molding operation.

In one embodiment, the electronic elements 21 are, for example, semiconductor chips, and the electronic elements 21 can be electrically connected to the carrier structure 20 via flip chip method or wire bonding method. The encapsulation layer 22 is made of insulating material, such as polyimide (PI) or encapsulating adhesive material of epoxy. The type of the electronic module 2, the electrical connection method between the electronic elements 21 and the carrier structure 20, and the material and formation method of the encapsulation layer 22 are not limited to the above.

Please refer to FIG. 2 and FIG. 3B at the same time. Next, the packaging method includes step S22: performing a humidifying operation. After the molding operation is completed, the electronic module 2 formed with the encapsulation layer 22 is placed in a humidifying device 32, that is, the electronic module 2 formed with the encapsulation layer 22 is placed in a high-humidity environment, so that the encapsulation layer 22 (made of encapsulating adhesive material) absorbs moisture.

In one embodiment, the humidifying device 32 is, for example, a humidifying chamber (but is not limited to as such). The humidifying device 32 is provided primarily with a multi-layer frame 321 in a chamber 320 for placing a plurality of the electronic modules 2, and the humidifying device 32 sprays a humidifying liquid 322 such as water in the chamber 320 to form the chamber 320 as a high humidity environment.

Please refer to FIG. 2 and FIG. 3C at the same time. Afterwards, the packaging method includes step S23: performing a drying operation. After the encapsulation layer 22 (made of encapsulating adhesive material) absorbs moisture, the electronic module 2 is taken out from the humidifying device 32 and is placed in a drying device 33.

In one embodiment, the drying device 33 is, for example, an oven (but not limited to as such), and the drying device 33 uses a pressure oven or is fixed with a clamp for pressure baking, thereby removing the moisture absorbed in the high-humidity environment. Therefore, the encapsulation layer 22 (made of encapsulating adhesive material) is completely solidified, and the warpage caused by the shrinkage or expansion deformation of the encapsulation layer 22 (made of encapsulating adhesive material) during the aforementioned molding operation can be shaped within a certain extent and restored to its original shape.

As shown in FIG. 3A to FIG. 3C, the present disclosure discloses a packaging equipment. The packaging equipment includes a molding device 31, a humidifying device 32 and a drying device 33.

The molding device 31 forms an encapsulation layer 22 on the electronic module 2 to cover and protect the electronic elements 21 of the electronic module 2, wherein the process of forming the encapsulation layer 22 may cause the electronic module 2 to warp, such as bending upward resembling a smiling face or bending downward resembling a crying face.

The humidifying device 32 is configured to be connected to the molding device 31 to humidify the encapsulation layer 22.

The drying device 33 is configured to be connected to the humidifying device 32 to remove moisture from the encapsulation layer 22 and fully solidify the encapsulation layer 22. At the same time, the electronic module 2 formed with the encapsulation layer 22 is shaped to reduce the extent of warpage.

To sum up, in the packaging equipment and packaging method of the present disclosure, an electronic module is placed in a molding device for a molding operation. After an encapsulation layer is formed, the electronic module is moved to a humidifying device, and the humidifying device is used to perform a humidifying operation to the encapsulation layer. Then, the electronic module is moved to a drying device, and the drying device is used to perform a drying operation to remove moisture from the encapsulation layer and fully solidify the encapsulation layer. At the same time, the electronic module's warpage caused by the deformation of the encapsulation layer can be shaped within a certain extent to prevent the problem of cracking from occurring to the electronic package. At the same time, the aforementioned packaging equipment and packaging method can solve existing technical problems in the industry without adding new development processes and materials. Therefore, there will not be a large amount of additional costs, nor will the existing product structure be changed, and the existing specifications of the end product can be met.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A packaging equipment, comprising:
a molding device configured to form an encapsulation layer on an electronic module; and
a humidifying device configured to be connected to the molding device to humidify the encapsulation layer.

2. The packaging equipment of claim 1, further comprising a drying device configured to be connected to the humidifying device to remove moisture from the encapsulation layer while shaping the electronic module formed with the encapsulation layer.

3. The packaging equipment of claim 1, wherein the electronic module includes a carrier structure and electronic elements disposed on the carrier structure.

4. The packaging equipment of claim 1, wherein the electronic module is in a circular or rectangular form.

5. The packaging equipment of claim 4, wherein the electronic module has a circular shape of 8 inches to 18 inches.

6. The packaging equipment of claim 4, wherein the electronic module has a rectangular side length of 300 mm to 700 mm.

7. The packaging equipment of claim 1, wherein the humidifying device is used to place the electronic module formed with the encapsulation layer in a high-humidity environment to allow the encapsulation layer to absorb moisture.

8. The packaging equipment of claim 1, wherein the molding device is a molding mold including an upper mold and a lower mold.

9. The packaging equipment of claim 1, wherein the humidifying device is a humidifying chamber.

10. The packaging equipment of claim 2, wherein the drying device uses a pressure oven or is fixed with a clamp to perform pressure baking to remove moisture from the encapsulation layer.

11. The packaging equipment of claim 2, wherein the drying device is an oven.

12. A packaging method, comprising:
placing an electronic module in a molding device to form an encapsulation layer on the electronic module; and
placing the electronic module formed with the encapsulation layer in a humidifying device to humidify the encapsulation layer.

13. The packaging method of claim 12, further comprising, after the encapsulation layer absorbs moisture, placing the electronic module formed with the encapsulation layer in a drying device to remove moisture from the encapsulation layer while shaping the electronic module formed with the encapsulation layer.

14. The packaging method of claim 12, wherein the electronic module includes a carrier structure and electronic elements disposed on the carrier structure.

15. The packaging method of claim 12, wherein the electronic module is in a circular or rectangular form.

16. The packaging method of claim 15, wherein the electronic module has a circular shape of 8 inches to 18 inches.

17. The packaging method of claim 15, wherein the electronic module has a rectangular side length of 300 mm to 700 mm.

18. The packaging method of claim 12, wherein the humidifying device is used to place the electronic module formed with the encapsulation layer in a high-humidity environment to allow the encapsulation layer to absorb moisture.

19. The packaging method of claim 12, wherein the molding device is a molding mold including an upper mold and a lower mold.

20. The packaging method of claim 12, wherein the humidifying device is a humidifying chamber.

21. The packaging method of claim 13, wherein the drying device uses a pressure oven or is fixed with a clamp to perform pressure baking to remove moisture from the encapsulation layer.

22. The packaging method of claim 13, wherein the drying device is an oven.
